(19) United States
(12) Patent Application Publication
(10) Pub. No.: US 2008/0231477 A1
(43) Pub. Date: Sep. 25, 2008

(54) INPUTTING INFORMATION USING A SCROLL KEY

(75) Inventors: Jong Sung Kim, Seoul (KR); Gyu Hoon Jeong, Seoul (KR)

Correspondence Address: LEE, HONG, DEGERMAN, KANG & SCHMADEKA, 660 S. FIGUEROA STREET, Suite 2300, LOS ANGELES, CA, 90017, US

(73) Assignee: LG Electronics Inc.

(21) Appl. No.: 12/053,510

(22) Filed: Mar. 21, 2008

(30) Foreign Application Priority Data
Mar. 22, 2007 (KR) 10-2007-0028046

(51) Int. Cl. H03M 11/00

(52) U.S. Cl. 341/20

(57) ABSTRACT

A method and apparatus for inputting data using a mobile terminal having a scroll key as a user interface. The method includes entering a mode configured to receive a data code created using at least the scroll key, detecting the data code that comprises at least one movement of the scroll key in a first or second direction in a predetermined sequence pattern, and activating one of a plurality of functions of the mobile terminal in response to detecting the data code.

Pursuant to 35 U.S.C. § 119(a), this non-provisional patent application claims the benefit of the earlier filing date and right of priority of Patent Application No. 10-2007-0028046, filed in Republic of Korea on Mar. 22, 2007, the entire contents of which are hereby incorporated by reference.

### FIELD OF INVENTION

The present invention is directed to inputting information in a mobile terminal using a scroll key.

### DESCRIPTION OF RELATED ART

Conventional mobile terminals are equipped with a scroll key or a jog dial for navigating through menus. The scroll key is scrolled up and down, or to the left and right, and pressed down to select and execute almost every menu provided by the mobile terminal.

However, the conventional mobile terminal does not provide scroll key menu functions requiring inputs of numbers or characters.

### SUMMARY OF THE INVENTION

In one general aspect of the present invention, a method for inputting data using a mobile terminal having a scroll key as a user interface is provided. The method includes entering a mode for receiving a data code created using at least the scroll key, detecting the data code that comprises at least one movement of the scroll key in a first or second direction, in a predetermined sequence pattern, and activating one of a plurality of functions of the mobile terminal in response to detecting the data code.

It is contemplated that the mode comprises a password input mode. It is further contemplated that the data code further comprises at least one input received using a keypad of the mobile terminal.

It is contemplated that the data code comprises at least one alphanumerical character. It is further contemplated that the keypad comprises a virtual touch screen keypad to recognize contacts through a touch screen display.

It is contemplated that the predetermined sequence pattern includes a pause between each movement of the scroll key. It is further contemplated that the predetermined sequence pattern comprises confirming an input after each movement of the scroll key.

It is contemplated that detecting the data code includes detecting at least one angular movement of the scroll key in the first or the second direction in the predetermined sequence pattern.

It is contemplated that the first and the second directions comprise upward and downward movements, respectively. It is further contemplated that the first and the second directions comprise rightward and leftward movements, respectively.

It is contemplated that the predetermined sequence pattern comprises at least one of an increment and a decrement of an input value corresponding to each movement of the scroll key.

In another general aspect of the invention, a mobile terminal, includes a user interface including a scroll key, an input unit for receiving a data code created using at least the scroll key, a controller entering a mode for receiving the data code, detecting the data code comprising at one least movement of the scroll key in a first or second direction in a predetermined sequence pattern, and activating one of a plurality of functions of the mobile terminal in response to detecting the data code.

The foregoing and other objects, features, aspects and advantages of the present invention will become more apparent from the following detailed description of the present invention when taken in conjunction with the accompanying drawings.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention.

FIGS. 1A-1C illustrate front views of a mobile terminal having a scroll key according to an embodiment of the present invention.

FIG. 2 is a block diagram of a mobile terminal in accordance with the embodiment of the present invention.

FIG. 3 is a flowchart illustrating a method for inputting information using a scroll key of a mobile terminal according to an embodiment of the present invention.

FIG. 4 illustrates a window for inputting a password according to an embodiment of the present invention.

FIG. 5 illustrates a scroll key scrolled down.

FIG. 6 illustrates a scroll key scrolled up.

FIG. 7 depicts the screen for indicating a password input using the scroll key.

### DETAILED DESCRIPTION OF PREFERRED EMBODIMENTS

In the following detailed description reference is made to the accompanying drawing figures which form a part hereof, and which show by way of illustration specific embodiments of the invention. It is to be understood by those of ordinary skill in this technological field that other embodiments may be utilized, and structural, electrical, as well as procedural changes may be made without departing from the scope of the present invention. Wherever possible, the same reference numbers will be used throughout the drawings to refer to the same or similar parts.

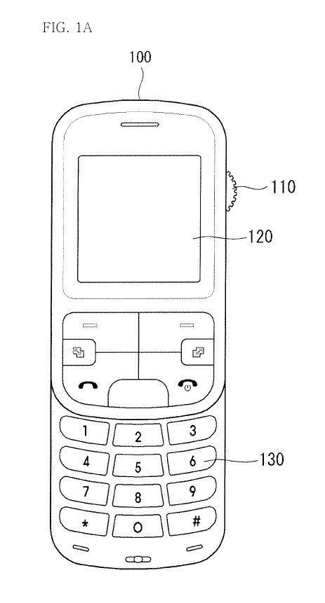

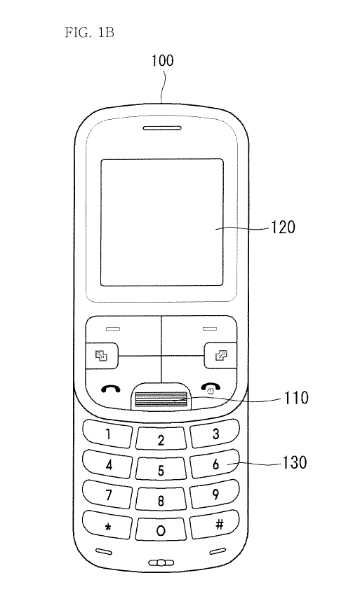

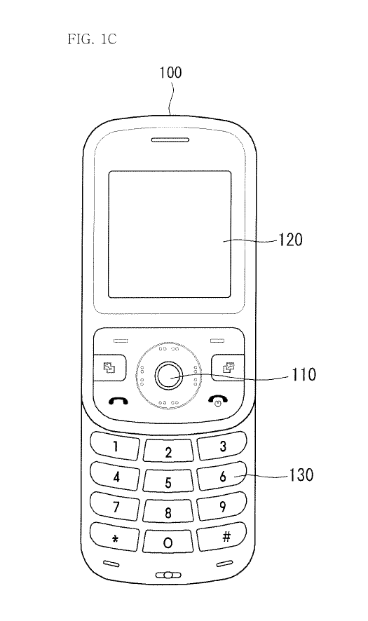

FIG. 1A is a front view of a mobile terminal 100 having a scroll key 110 according to an embodiment of the present invention. FIGS. 1B and 1C illustrate variations of the scroll key 110 depicted in the mobile terminal 100 of FIG. 1A.

Referring to FIG. 1A, the mobile terminal 100 comprises a scroll key 110 for inputting information via a scrolling operation, a display 120 for displaying the information inputted via the scrolling operation of the scroll key, and a key input 130 having a plurality of key buttons. The key input may include a virtual touch screen keypad to recognize contacts through a touch screen display.

The information input via the scrolling operation of the scroll key 110 may include signs to be used as a password. The information may be combined with numbers or characters input via the key input 130 to form a password. The scrolling operation performed by the scroll key 110 may include upward and downward movements, or leftward and rightward rotations.

Referring to FIG. 1A, the scroll key 110 is disposed at an upper right side of the mobile terminal 100 to provide a user with the convenience of operation. Other positions for the scroll key may include an upper left side, lower side parts, and a front part of the mobile terminal 100.

As illustrated in FIG. 1B, the scroll key 110 may be disposed between the display 120 and the key input 130 at a front side of the mobile terminal 100. With reference to FIG. 1C, the scroll key 110 may be implemented as a jog dial capable of rotating clockwise (rightward) and counterclockwise (leftward) for performing a scrolling operation.

As illustrated in FIG. 1C, the jog dial 110 is disposed in the key input 130 portion on the front side of the mobile terminal 100. The jog dial may be disposed at another part of the mobile terminal 100, such as an upper front side or a lower front side.

The scroll key 110 may be scrolled or rotated in a step manner and pressed down to enter a corresponding command. For example, if the scroll key 110 is scrolled two steps up and one step down and then pressed down, a command corresponding to the two steps up and one step down of the scroll key 110 may be entered.

FIG. 2 is a block diagram of the mobile terminal 100. The mobile terminal 100 further includes a transceiver 210, a controller 230, and a memory 240, in addition to the scroll key 110, the display 120, and the key input 130.

The elements of the mobile terminal 100 are connected via a central bus 220. However, some of the elements may be connected to other elements via their own buses or cables. Furthermore, some elements may be wirelessly connected to other elements. The transceiver 210 transmits and receives voice signals for establishing a call or multimedia data through a communication network with another end terminal.

The display 120 displays operation status of the mobile terminal 100. The display 120 may display symbols to indicate that a password is being input.

The key input 130 includes the plurality of key buttons such as number, symbol, and character keys. The scroll key 110 may be integrated into the key input 130. The key input 130 receives an operation command from a user and outputs a corresponding key input signal to the controller 230.

For example, a user may select any of the number, character, and symbol keys from the key input 130 by pressing down. A key input signal is then generated corresponding to the pressed key and the key input signal is transmitted to the controller 230.

The memory 240 stores programs and data for controlling overall operations of the mobile terminal 100. The memory 240 may store menus and programs for controlling the scroll key 110 and the key input 130 in order to facilitate the input of information data, such as a command or a password, including numbers, characters, or signs that are entered by scrolling or pressing down the scroll keys.

The memory 240 may store input information data corresponding to each of the scrolling operations of the scroll key 110. For example, the user may set a symbol input corresponding to each of the scrolling operations and the set symbol inputs are stored in the memory 240 in relation to the scrolling operations. The controller 230 may recognize the symbol input corresponding to the scrolling operations upon receiving the scrolling operations from the scroll key 110 using the data stored at the memory 240.

The memory 240 may store a password preset by the user that is entered by using the scroll key 110 or using both the scroll key 110 and the key input 130. The memory 240 may buffer the information data input using the scroll key 110 or the key input 130, such as the password or command corresponding to the scrolling operations, or the key input signals from the key input 130.

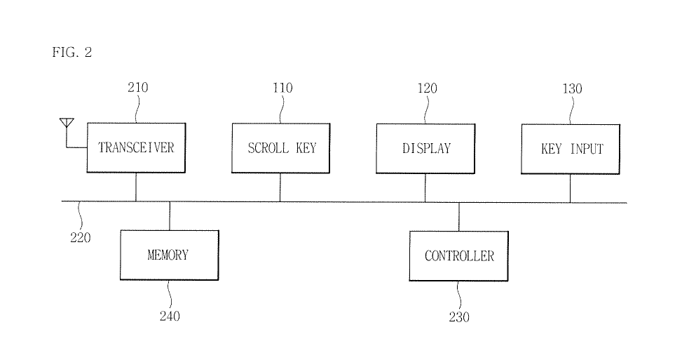

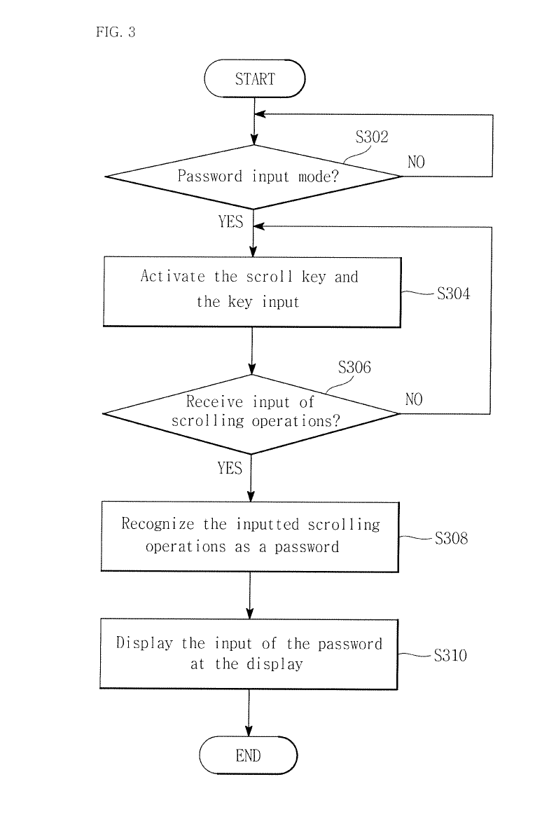

FIG. 3 is a flowchart illustrating a method for inputting information using the scroll key 110 of the mobile terminal 100. Referring to FIG. 3, the mobile terminal 100 enters into a password input mode to receive the password from the user if the user selects a menu requiring a password (S302).

For example, the user may select a menu requiring a password in order to operate the mobile terminal 100 using the scroll key 110. The controller 230 may store a combination of scrolling operations for the scroll key 110 as the password preset by the user.

In practice, one step movement of the scrolling operation may constitute one symbol of the password. For example, the controller 230 may set a combination pre-selected by the user that includes upward, downward, leftward or rightward scrolling operations of the scroll key 110 as the password and store the combination in the memory 240.

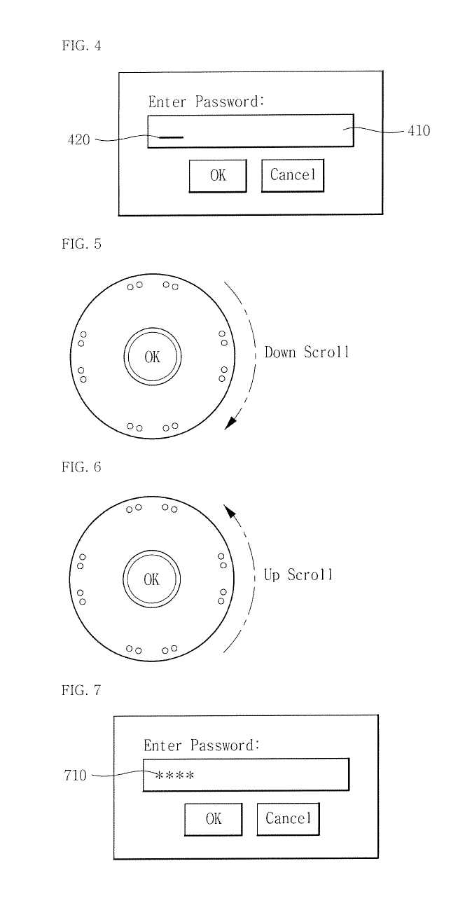

FIG. 4 illustrates a screen for inputting the password. The controller 230 displays on the display 130 the password input screen, and activates the scroll key 110 and the key input 130 in the password input mode (S304).

Referring to FIG. 4, the screen for inputting the password includes a password input window 410 having a cursor indicating where to input the password. The password input window 410 displays every input of the password in the form of symbols. The screen for inputting the password may further include an ‘OK’ button to confirm the input password and a ‘CANCEL’ button to cancel the input password.

FIGS. 5 and 6 illustrate scroll keys scrolled down and up, respectively. As shown in FIGS. 5 and 6, the user may perform a downward scrolling operation or an upward scrolling operation while checking the password input window 410.

The controller 230 determines if the scroll input mode is activated to receive the password (S306). Accordingly, the controller 230 receives input signals from the scroll key 110 corresponding to scrolling operations by the user.

The scrolling operations may include a plurality of steps. Each step may correspond to a single movement of the scroll key 110. For example, a step may correspond to an upward movement or a downward movement of the scroll key 110. The step may also correspond to a leftward or a rightward movement of the scroll key 110. Alternatively, the scrolling operation may be performed by rotation of the scroll key 110 in a predetermined angle range or rotation of the scroll key followed by a stop of the rotation. The controller 230 may recognize the scrolling operations of the scroll key 110 as the password (S308) according to the input information data stored in the memory 240 for controlling the scroll key.

For example, the user may perform scrolling operations consisting of one upward operation, one downward operation, a second upward operation, and a third upward operation. The controller 230 in the password input mode may recognize input signals corresponding to the scrolling operations as one step of the upward operation, one step of the downward operation, one step of the upward operation, and one step of the upward operation as the password. The controller 230 may buffer the input signals corresponding to the scrolling operations recognized as the password in the memory 240.

Alternatively, the controller 230 may receive an input corresponding to each of the upward, downward, leftward, or rightward scrolling operations of the scroll key 110 if the each step of the scrolling operations is followed by pressing the scroll key 110 down. For example, the user performs one step of upward scrolling operation and then presses the scroll key 110 down.

Accordingly, the controller 230 receives an input corresponding to the one upward scrolling operation step of the scroll key 110. If the user then performs one downward scrolling operation step and presses the scroll key 110 down, one upward scrolling operation, and one more upward scrolling operation and presses the scroll key down, the controller 230 receives an input corresponding to each step of the scrolling operations.

FIG. 7 illustrates a screen indicating a password that was input using the scroll key 110. The controller 230 may display symbols “****” 710 in the password input window 410 (S310), as shown in FIG. 7. Each symbol corresponds to each step of the scrolling operation.

The controller 230 may move the cursor 420 displayed in the password input window 410 one place to the right as each digit of the password is input and another “*” is displayed.

As the user inputs the password using the scroll key 110, observers may not easily recognize the scrolling operations, thereby preventing the password from being revealed. The password may be set such that it is input from both the scroll key 110 and the key input 130 as a combination of scrolling operations of the scroll key and number or character keys of the key input. For example, a 4-digit password may include a first input of one upward step and a second input of a downward step by scrolling operations of the scroll key 110, a third input of a number ‘8’ key button, and a fourth input of a character “c” key button.

The controller 230 may receive a step number of scrolling operations of the scroll key 110 and recognize the step number as a number input. For example, an upward scrolling operation of the scroll key 110 may be counted as an increment of an input by one while a downward scrolling operation may be counted as a decrement by one. Alternately, the controller 230 may receive a corresponding number input when the user performs one or more upward scrolling operations followed by pressing the scroll key 110 down, or one or more downward scrolling operations followed by pressing the scroll key down.

The controller 230 may terminate the password input mode if a corresponding function key, such as the ‘OK’ key button shown in FIGS. 5 and 6 is pressed. The scroll key 110 may be used to navigate through the menus or icons displayed on the display 120 upon termination of the password input mode.

For example, the controller 230 may move the cursor 420 in the password input window 410 to the right or left, or up or down, if the scroll key 110 is scrolled rightward or leftward, or upward or downward, such that the cursor is positioned at a desired menu or an icon in order to execute a function corresponding to the menu or the icon. The controller 230 may confirm the password input via the scrolling operations of the scroll key 110 if the user scrolls the scroll key downward to move the cursor 420 to a position of an ‘ENTER’ menu and presses the scroll key to confirm the previously input password.

Alternately, the controller 230 may delete a previously input password stored in the memory 240. If the user scrolls the scroll key 110 downward to move the cursor 420 to a position of a ‘CANCEL’ menu, and presses the ‘CANCEL’ menu,

The controller 230 may display an indicator in a shape of a scroll icon or a lock to indicate that the password is being input via scrolling operations of the scroll key 110, such that the user may recognize the result of manipulating the scroll key.

According to the above described features, the password may be input via scrolling operations of the scroll key 110 so that the user may effectively prevent the password from being revealed to others.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A method of inputting data using a mobile terminal comprising a scroll key as a user interface, the method comprising:
entering a mode for receiving a data code created using at least the scroll key;
detecting the data code that comprises at least one movement of the scroll key in a first or second direction, in a predetermined sequence pattern; and
activating one of a plurality of functions of the mobile terminal in response to detecting the data code.

2. The method of claim 1, wherein the mode comprises a password input mode.

3. The method of claim 1, wherein the data code further comprises at least one input received using a keypad of the mobile terminal.

4. The method of claim 3, wherein the data code comprises at least one alphanumerical character.

5. The method of claim 3, wherein the keypad comprises a virtual touch screen keypad to recognize contacts through a touch screen display.

6. The method of claim 1, wherein the predetermined sequence pattern comprises a pause between each movement of the scroll key.

7. The method of claim 1, wherein the predetermined sequence pattern comprises confirming an input after each movement of the scroll key.

8. The method of claim 1, wherein detecting the data code comprises detecting at least one angular movement of the scroll key in the first or the second direction in the predetermined sequence pattern.

9. The method of claim 1, wherein the first and the second directions comprise upward and downward movements, respectively.

10. The method of claim 1, wherein the first and the second directions comprise rightward and leftward movements, respectively.

11. The method of claim 1, wherein the predetermined sequence pattern comprises at least one of an increment and a decrement of an input value corresponding to each movement of the scroll key.

12. A mobile terminal, comprising:
a user interface comprising a scroll key;
an input unit for receiving a data code created using at least the scroll key;
a controller entering a mode for receiving the data code, detecting the data code comprising at one least movement of the scroll key in a first or second direction in a predetermined sequence pattern, and activating one of a plurality of functions of the mobile terminal in response to detecting the data code.

13. The mobile terminal of claim 12, wherein the mode comprises a password input mode.

14. The mobile terminal of claim 12, wherein the data code further comprises at least input received using a keypad.

15. The mobile terminal of claim 14, wherein the data code comprises at least one alphanumerical character.

16. The mobile terminal of claim 14, wherein the keypad comprises a virtual touch screen keypad to recognize contacts through a touch screen display.

17. The mobile terminal of claim 12, wherein the predetermined sequence pattern comprises a pause between each movement of the scroll key.

18. The mobile terminal of claim 12, wherein the predetermined sequence pattern comprises confirming an input after each movement of the scroll key.

19. The mobile terminal of claim 12, wherein the controller detects at least one angular movement of the scroll key in the first or the second direction in the predetermined sequence pattern.

20. The mobile terminal of claim 12, wherein the first and the second directions comprise upward and downward movements, respectively.

21. The mobile terminal of claim 12, wherein the first and the second directions comprise rightward and leftward movements, respectively.

22. The mobile terminal of claim 12, wherein the predetermined sequence pattern comprises at least one of an increment and a decrement of an input value corresponding to each movement of the scroll key.
